(19) United States
(12) Patent Application Publication
(10) Pub. No.: US 2017/0163126 A1
(43) Pub. Date: Jun. 8, 2017

(54) INTERFERENCE SUPPRESSION FILTER FOR A DC MOTOR AND DC MOTOR HAVING SAID FILTER

(71) Applicant: Robert Bosch GmbH, Stuttgart (DE)

(72) Inventors: Claus SCHMIEDERER, Rheinau (DE); Suhas JAWALE, Karlsruhe (DE); Marcel GORGES, Karlsruhe (DE)

(21) Appl. No.: 15/039,562

(22) PCT Filed: Sep. 25, 2014
(86) PCT No.: PCT/EP2014/070504

§ 371 Date: May 26, 2016

(30) Foreign Application Priority Data
Nov. 28, 2013 (DE) 10 2013 224 458.4

(51) Int. Cl. H02K 11/02; H03H 7/01

(52) U.S. Cl. CPC H02K 11/02; H03H 7/0115

(57) ABSTRACT

The present invention relates to an interference suppression filter for a DC motor (2), comprising two inductors (11, 12) each arranged in a supply line (31, 32) and a Cx capacitor (13) arranged between the supply lines (31, 32) as well as a Cy capacitor (14) arranged between one of the two supply lines (31, 32) and earth (M), wherein the impedances of the inductors (11, 12), of the Cx capacitor (13) and/or of the Cy capacitor (14) are dimensioned in such a manner that a high-frequency interference current which flows in the other of the two supply lines flows away via the Cx capacitor (13) and the Cy capacitor (14). The present invention also relates to a DC motor having the interference suppression filter.

### BACKGROUND OF THE INVENTION

The present invention relates to a DC motor having an interference suppression filter.

In the case of electric commutator machines, gas discharges occur between the commutator segments and the brushes which pass over the commutator segments, in particular during the transition of a brush from one commutator section to the next. The gas discharges manifest themselves in current spikes and cause high-frequency interference emissions. Fast changes in current, for example during switch-on and switch-off processes of electrical loads, also cause electromagnetic harmonics in the range of a very broad frequency band.

In order to reduce interference emissions, the emergence of such interferences is reduced by limiting the increase in current in addition to shielding the sources of interference; or interference suppression filters are provided which filter the signals in the supply lines from and to the source of interference. Such suppression filters are usually constructed from resistors, capacitors and/or inductors.

In regard to the interference emissions, a differentiation is made between differential-mode interferences and common-mode interferences. High-frequency voltages between the conductors of the power cables are denoted as differential-mode interferences. RFI voltages to earth are referred to as common-mode interferences.

FIG. 1 shows a DC motor 2 having a conventional interference suppression filter 1. Conventional interference suppression filters 1 comprise two interference suppression inductors 11, 12 disposed in the supply lines 31, 32, said inductors limiting the increase in current during switching processes, and a Cx capacitor 13 which is disposed between the supply lines 31, 32 (positive connection/negative connection) and which is used as a short circuit for the high-frequency interference currents. The differential-mode interference is attenuated with such an interference suppression filter 1. Such a filter is, however, only effective up to approximately 8-10 MHz on account of resonance effects of the inductors 11, 12 and the parasitic capacity of the DC motor 2, the housing of which does not lie at zero potential. In contrast, a broadband interference suppression requires a complete interference suppression with an interference suppression filter 1, which furthermore comprises two Cy capacitors 14, 15. The Cy capacitors 14, 15 are each provided between one of the two supply lines 31, 32 and earth M and attenuate the common-mode interferences. They act as short circuits for high-frequency interference currents. The housing of the DC motor 1, in particular the pole pot of the DC motor, serves primarily as the earth for the Cy capacitors.

### SUMMARY OF THE INVENTION

It is the aim of the present invention is to provide a DC motor having a cost effective, broadband interference suppression filter, in particular consisting of wired components, which can be disposed in a limited space of the brush holder of the DC motor. The interference suppression filter is capable of attenuating a line-borne interference radiation in the frequency range of 150 kHz-110 MHz and therefore effect a complete interference suppression.

The aim of the invention is met by an interference suppression filter as well as by a DC motor.

To this end, an interference suppression filter is provided for a DC motor which comprises two inductors each arranged in a supply line and a Cx capacitor arranged between the supply lines as well as a Cy capacitor arranged between one of the two supply lines and earth. The interference suppression filter is characterized in that the impedances of the inductors of the Cx capacitor and/or the Cy capacitor are dimensioned in such a manner that that a high-frequency interference current which flows in the other of the two supply lines flows away via the Cx capacitor and the Cy capacitor to earth.

In this regard, an interference current in the frequency range of 150 kHz-110 MHz, in particular from 30 MHz-110 MHz, is referred to as a high-frequency interference current.

The interference suppression filter comprises exactly one Cy capacitor. The Cy capacitor conventionally connected to the other of the two supply lines is therefore omitted in this interference suppression filter. The components of the interference suppression filter are nevertheless dimensioned in such a manner that the interference suppression filter ensures a complete interference suppression, particularly in the frequency range of at least 150 kHz-110 MHz.

Fewer natural resonances occur due to the omission of Cy capacitor and the resulting reduced number of the interference suppression components. A brush holder for a DC motor having this interference suppression filter can furthermore be produced more compactly on account of the fewer number of components and can be adapted more easily to the installation space dimensions. Moreover, the costs and the manufacturing effort for the interference suppression filter are reduced.

The interference suppression filter is preferably produced from line-borne interference suppression components and is thus suitable for attenuating a line-borne interference radiation. In an especially preferred manner, the Cx capacitor, the Cy capacitor and/or the inductors are designed as wired components. A manufacture from SMD components (surface mounted device) is, however, also preferred.

The impedances of the two inductors are preferably the same. With regard to a differential-mode interference, the interference suppression filter of this embodiment is therefore symmetrically constructed.

In order that the high-frequency interference current, which flows in the other of the two supply lines, flows away to earth via the Cx capacitor and the Cy capacitor, it is preferred that a total impedance of said capacitors of the interference suppression filter, which results by adding the impedance of the Cx capacitor to that of the Cy capacitor, is less than the impedance of the inductors: Z_{Cx}+Z_{Cy1}<<Z_{L}.

In so doing, it is preferred that parasitic inductances of electrical connection lines of the interference suppression filter are small, particularly preferably negligibly small for the high-frequency current flowing in the other of the two supply lines. Inductive components of the line impedance of the electrical connection lines are referred to here as parasitic inductances. The electrical connection lines are preferably those of the current path, via which the high-frequency interference current flows to earth. Said lines therefore comprise the other of the two supply lines as well as the electrical connection lines to the Cx capacitor, to the Cy capacitor and to earth.

To this end, it is furthermore preferred that the electrical connection lines of the interference suppression filter, in particular in the current path via which the high-frequency interference current flows to earth, are designed to be short. As a result, the parasitic inductances are reduced.

In a preferred embodiment, the inductive component of the impedance of the Cx capacitor is furthermore smaller than or equal to that of the Cy capacitor for the high-frequency interference current flowing in the other of the two supply lines. It is, however, particularly preferred that the inductive component of the impedance of the Cx capacitor is significantly smaller than that of the Cy capacitor.

In a preferred embodiment, which likewise meets the aim of the invention, an interference suppression filter is provided for a DC motor, which comprises the two inductors that are arranged in the supply lines and have the same impedance. Said interference suppression filter also comprises the Cx capacitor arranged between the supply lines as well as the Cy capacitor arranged between the one of the two supply lines and earth. The interference suppression filter of this embodiment is characterized in that a total impedance of the Cx capacitor and the Cy capacitor is smaller than an impedance of the inductors, wherein an inductive component of the impedance of the Cx capacitor is smaller than an inductive component of the impedance of the Cy capacitor in the case of a high-frequency interference current flowing in the other of the two supply lines; thus enabling the high-frequency interference current to flow away to earth via the Cx capacitor and the Cy capacitor.

In the case of the interference suppression filter of this embodiment, an interference current in the frequency range of 150 kHz-110 MHz, in particular from 30 MHz-110 MHz, is also referred to as a high-frequency interference current.

This interference suppression filter according to the invention also comprises exactly the one Cy capacitor, so that the Cy capacitor conventionally connected to the other of the two supply lines is omitted. As a result, fewer natural resonances occur also with this interference suppression filter. A brush holder for a DC motor having said interference suppression filter can also be more compactly manufactured due to the fewer number of components, can be adapted more easily to the installation space dimensions; and the costs and the manufacturing effort for said interference suppression filter are reduced.

In a preferred manner, this interference suppression filter is also manufactured from line-borne interference suppression components.

The following designs apply to both embodiments of the interference suppression filter.

In a further preferred manner, the total impedance of these capacitors is approximately equal to or less than the impedance of the second Cy capacitor connected to the other of the two supply lines in conventional interference suppression filters: Z_{Cx}+Z_{Cy1}≦Z_{Cy2}.

In a particularly preferred manner, an inductive component of an impedance of the Cx capacitor and/or an inductive component of an impedance of the Cy capacitor for the high-frequency interference current flowing in the other of the two supply lines is/are less than the inductive component of the impedance of the inductors.

In a most particularly preferred manner, the inductive component of the total impedance of the capacitors of the interference suppression filter for the high-frequency interference current flowing in the other of the two supply lines is less than the inductive component of the impedance of the inductors.

The inductance of the inductors is preferably approximately 50 nH-20 μH, particularly preferably approximately 1μH-7 μH. The capacity of the Cx capacitor is preferably approximately 400 pF-10 μF, particularly preferably approximately 680 pF-3 μF. The capacity of the Cy capacitor is preferably approximately 1-50 nF, particularly preferably approximately 8-12 nF.

In this case, the one supply line is either a supply line connected to a positive pole of a DC voltage source, wherein the other of the two supply lines is a supply line connected to a negative pole of the DC voltage source, or vice-versa. The selection, to which of the two supply lines the Cy capacitor is connected, is preferably determined by the installation space dimensions in the brush holder. A lead frame is preferably used for the supply lines. In so doing, it is preferred that an impedance of the lead frame, in particular an inductive component of the impedance of the lead frame, is negligibly small when high-frequency interference current is flowing across the lead frame.

The aim of the invention is furthermore met by means of a DC motor (DC motor, direct current), in particular for a motor vehicle, comprising such an interference suppression filter. Due to the omission of the Cy capacitor and the resulting reduced number of interference suppression components, the costs and the manufacturing effort are reduced for the DC motor.

The interference suppression filter is preferably disposed in the region of the brush holder or on the brush holder. The brush holder of the DC motor can be more compactly manufactured due to the smaller number of components and can be more easily adapted to the installation space dimensions of the DC motor and/or the mounting dimensions.

The DC motor therefore comprises the two inductors each arranged in one of the two supply lines to said DC motor and the Cx capacitor arranged between the supply lines, said inductors and Cx capacitor attenuating the differential-mode interference. And instead of having two Cy capacitors, the interference suppression filter of the DC motor has only one Cy capacitor. This Cy capacitor is disposed between a first of the two supply lines of the DC motor and an earth connection. In so doing, it is preferred that the housing, in particular the pole pot of the DC motor, is used as earth to which the Cy capacitor is attached. Said earth connection is referred to below as a floating earth.

The impedances of the inductors, of the Cx capacitor and/or of the Cy capacitor of the interference suppression filter of this DC motor, in particular the inductive components thereof, are dimensioned in such a manner that a high-frequency interference current which flows in the other of the two supply lines, to which a Cy capacitor is not connected, flows away via the Cx capacitor and the Cy capacitor to the floating earth. In this interference suppression filter, the common-mode interferences are therefore attenuated via the one Cy capacitor and the Cx capacitor.

### BRIEF DESCRIPTION OF THE DRAWINGS

In the following, the invention is described by means of the drawings. The figures in the drawings are only provided by way of example and do not limit the general inventive concept. In the drawings:

FIG. 1 shows a DC motor comprising a conventional interference suppression filter which is provided for the completed interference suppression of interference emissions;

FIG. 2a shows a DC motor comprising a first embodiment of an interference suppression filter;

FIG. 2b shows the DC motor comprising a second embodiment of the interference suppression filter; and

FIG. 3 shows by way of example frequency responses of an interference emission of a common-mode interference with different interference suppression filters.

### DETAILED DESCRIPTION

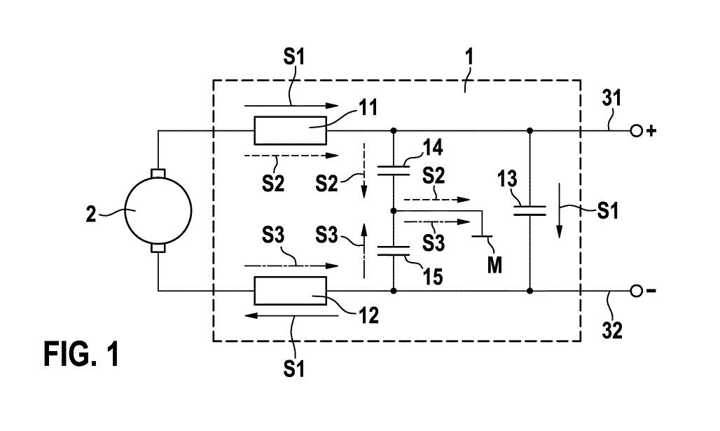

FIG. 1 shows the conventional interference suppression filter which has already been described above.

A first interference current S1 of a differential-mode interference is schematically delineated in the circuit. The first interference current S1 flows away via the path of the lowest impedance. Because the Cx capacitor 13 for high frequencies constitutes a short circuit, the first interference current S1 of the common-mode interference flows from the DC motor 2 across the inductor 11 arranged in the first supply line 31, across the Cx capacitor, across the inductor 12 arranged in the second supply line 32 and back to the DC motor. The inductors have an identical impedance in the circuit shown here.

A second interference current S2 of a common-mode interference flowing in the first supply line 31 flows from away the DC motor 2 via the first inductor 11 disposed in the first supply line 31 and via the first Cy capacitor 14 to earth M.

A third interference current S3 of a common-mode interference flowing in the second supply line 32 flows away from the DC motor 2 via the second inductor 12 disposed in the second supply line 32 and via the second Cy capacitor 15 to earth M.

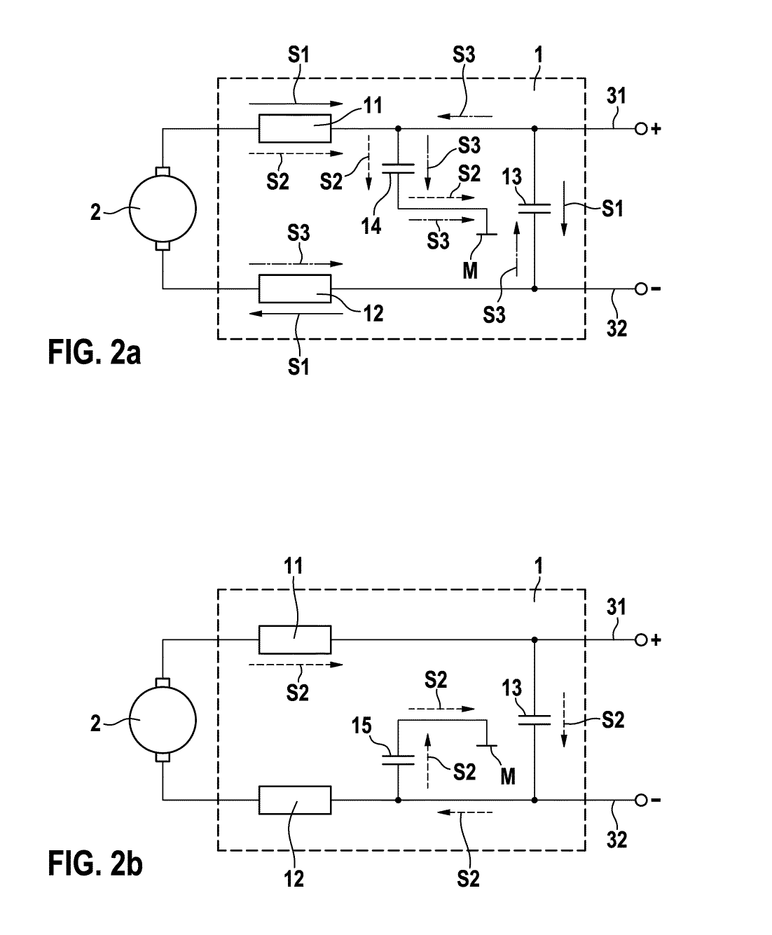

FIG. 2 shows in (a) a DC motor 2 comprising a first embodiment of an interference suppression filter 1 according to the invention. In this embodiment, the second Cy capacitor 15 connected to the second supply line 32 is omitted. The one supply line 31, to which the one Cy capacitor 14 of the inventive interference suppression filter 1 is connected, is then here the POSITIVE line of a DC voltage source (not depicted). The interference current flowing in the other of the two supply lines 32 is subsequently denoted here as the third interference current S3. The interference suppression filter 1 otherwise corresponds to that of FIG. 1.

It can be seen that the third interference current S3 flowing across the second supply line 32, which is the NEGATIVE supply line, flows here in a third current path, which leads from the second supply line 32 via the Cx capacitor 13 to the first supply line 31 and from there via the first Cy capacitor 14 to earth M. The third interference current S3 therefore flows away from the second supply line 32 via said third current path to mass M.

In the case of the DC motor 2 comprising the second embodiment of the inventive interference suppression filter 1 of FIG. 2 (b), the first Cy capacitor 14 connected to the first supply line 31 is omitted. The one supply line 31, to which the one Cy capacitor 15 of the interference suppression filter 1 according to the invention is connected, is thus here the NEGATIVE line of the DC voltage source. The interference current flowing in the other of the two supply lines 31 is denoted below as the second interference current S2. The interference suppression filter 1 otherwise corresponds to that of FIG. 1.

It can be seen that the second interference current S2 flowing across the first supply line 31, which is the POSITIVE supply line, flows here in a second current path, which leads from the first supply line 31 via the Cx capacitor 13 to the second supply line 32 and from there via the second Cy capacitor 15 to earth M. The second interference current S2 therefore flows from the first supply line 31 via said second current path to earth M.

In order that the second interference current S2 of the interference filter 1 of FIG. 2 (b) or the third interference current S3 of the interference filter 1 of FIG. 2 (a) flows away via the Cx capacitor 13 and the one Cy capacitor 14, 15 to earth, the total impedance Z_{Cx}+Z_{Cy1} of these capacitors 13, 14 of the interference suppression filter 1 is selected small with respect to the impedance Z_{L} of the inductors 11, 12.

In addition, the Cx capacitor 13 and the Cy capacitor 14 (FIG. 2(a)), 15 (FIG. 2(b)) are dimensioned in such a manner that an inductive component L_{Cx} of the impedance Z_{Cx} of the Cx capacitor 13 for a high-frequency interference current S2, S3 flowing in the other of the two supply lines 32 (FIG. 2(a)), 31 (FIG. 2(b)) is smaller than or equal to an inductive component L_{Cy1} of an impedance Z_{Cy1} of the Cy capacitor 14, 15. The inductive component L_{Cx} of the impedance Z_{Cx} of of the Cx capacitor 13 is preferably selected smaller or even substantially smaller than the inductive component L_{Cy1} of an impedance Z_{Cy1} of the Cy capacitor 14, 15.

The Cx capacitor 13 and the Cy capacitor 14 (FIG. 2(a)), 15 (FIG. 2 (b)) are furthermore preferably dimensioned in such a manner that the inductive components L_{Cx}, L_{Cy} thereof are small with respect to that of the inductance L_{L} of the inductors 11, 12 for the high-frequency interference current S2, S3 flowing through the same.

In addition, parasitic inductances are reduced by shortening electrical connection lines, in particular electrical connection lines in the second current path of the interference suppression filter 1 of FIG. 2 (b) or the third current path of the interference suppression filter 1 of FIG. 2 (c). The parasitic inductances are preferably reduced in such a manner that said inductances are negligible.

As a result, a complete interference suppression in the frequency range of 150 kHz-110 MHz, in particular from 30 MHz-110 MHz, can be achieved with the inventive interference suppression filter 1 despite the omitted second Cy capacitor.

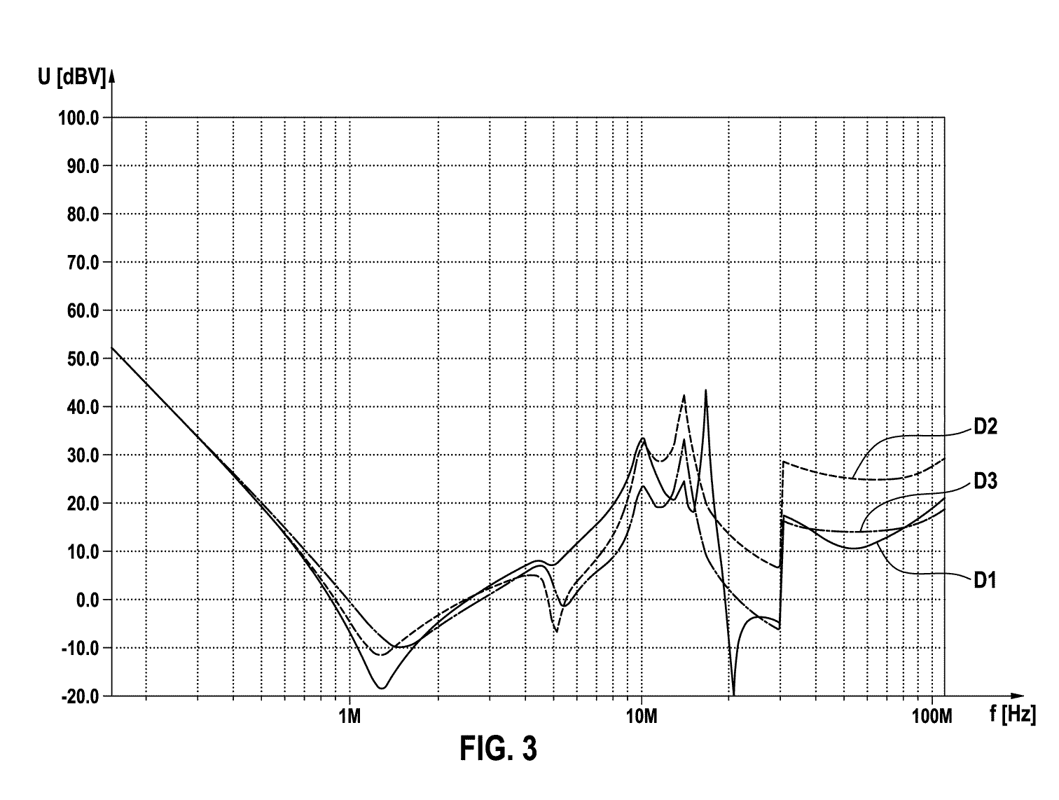

FIG. 3 shows by way of example three frequency responses D1-D3 of a line-borne interference voltage (CEV—conducted emission voltage) measured according to the international norm CISPR 25 edition 3 (Comité international special des perturbations radioélectriques). This interference voltage is a measure for the attenuation of the common-mode interference and differential-mode interference for a DC motor 2.

The first frequency response D1 shows the magnitude of the interference voltage of the common-mode interference for the DC motor 2 of FIG. 1 comprising a conventional interference suppression filter 1 as a function of the frequency. The second frequency response D2 shows the magnitude of the interference voltage of the common-mode interference of a circuit which corresponds to that of FIG. 2 (a), wherein the impedances Z_{Cx}, Z_{Cy1} of the Cx and the Cy capacitor 13, 14 of the circuit of this frequency response as well as the parasitic inductances are however not optimized. Finally, the third frequency response D3 shows the magnitude of the interference voltage of the common-mode interference with the inventive interference suppression filter of FIG. 2 (a), wherein the Cx capacitor 13, the Cy capacitor 14 and the line impedances of the electrical connection lines in the current paths conducting the interference current S2, S3 are optimized. The magnitudes of the interference voltage are depicted in each case in dbV with respect to the frequency f in Hz.

The impedances Z of the Cx and Cy capacitors 13-15 have a capacitive and an inductive component, so that they can be represented by the equation Z=1/jωC+jωL, where C is the capacitive component and L is the inductive component.

The conventional interference suppression filter 1 (see FIG. 1), with which the first frequency response D1 was measured, comprises inductors 11, 12 having an impedance Z_{L}, the inductance of which is L_{L} 1.5 μH. The impedance Z_{Cx} of the Cx capacitor 13 has a capacitive component C_{Cx} of 2.2 μF and an inductive component L_{Cx} of 6 nH; and the two Cy capacitors 14, 15 have an impedance Z_{Cy} comprising a capacitive component C_{Cy} of 10 nF and an inductive component L_{Cy} of 6 nH.

In the case of the interference suppression filter 1, with which the second frequency response D2 was measured, the inductors 11, 12 have an impedance Z_{L}, the inductance of which L_{L} is 1.5 μH. The impedance Z_{Cx} of the Cx capacitor 13 has a capacitive component C_{Cx} of 2.2 μF and an inductive component L_{Cx} of 6 nH; and the remaining Cy capacitor 14 has an impedance Z_{Cy1} comprising a capacitive component C_{Cy1} of 10 nF and an inductive component L_{Cy1} of 6 nH. Despite the omitted Cy capacitor, this second frequency response D2 shows an approximation of the first frequency response D1 up to approximately 4 MHz. From approximately 10 MHz, in particular from 30 MHz, the difference between the interference voltages U (D1), U (D2) is however more than 10 dB and is therefore insufficient.

In the case of the inventive interference suppression filter 1, with which the third, further optimized frequency response D3 was measured, the inductors 11, 12 have an impedance Z_{L}, the inductance L_{L} of which is 1.5 μH. The impedance Z_{Cx} of the Cx capacitor 13 has a capacitive component C_{Cx} of 2.2 μF and an optimized inductive component L_{Cx} of 2 nH; and the remaining Cy capacitor 14 has an impedance Z_{Cy1} comprising a capacitive component C_{Cy1} of 10 nF and an inductive component L_{Cy1} of 2 nH. In the present exemplary embodiment, the inductive components L_{Cx}, L_{Cy1} of the impedances Z_{Cx}, Z_{Cy1} of the Cy capacitors 13, 14 are therefore optimized.

It is apparent that, by further optimizing the impedances Z_{Cx}, Z_{Cy1} of the Cx capacitor and/or of the Cy capacitor 14 of the inventive interference suppression filter 1, a very good approximation of the attenuation of the interference emission of the common-mode interference that can be achieved by a conventional complete interference suppression is possible with said interference suppression filter 1, particularly in a frequency range greater than 30 MHz.

1. An interference suppression filter (1) for a DC motor (2), comprising two inductors (11, 12) each arranged in a supply line (31, 32) and a Cx capacitor (13) arranged between the supply lines (31, 32) as well as a Cy capacitor (14) arranged between one of the two supply lines (31) and earth (M),
characterized in that
the impedances of the inductors (11, 12) of the Cx capacitor (13) and the Cy capacitor (14) cause a high-frequency interference current (S2) which flows in the other of the two supply lines (32) to flow away via the Cx capacitor (13) and the Cy capacitor (14) to earth (M).

2. The interference suppression filter (1) according to claim 1, characterized in that the impedances of the two inductors are the same.

3. The interference suppression filter (1) according to claim 1, characterized in that a total impedance (Z_{Cx}+Z_{Cy1}) of the capacitors (13, 14) of the interference suppression filter (1) is less than the impedance (Z_{L}) of the inductors (11, 12).

4. The interference suppression filter (1) according to claim 1, characterized in that an inductive component (L_{Cx}) of an impedance (Z_{Cx}) of the Cx capacitor (13) for the high-frequency interference current (S2) flowing in the other of the two supply lines (32) is smaller than an inductive component (L_{Cy1}) of an impedance (Z_{Cy1}) of the Cy capacitor (14).

5. The interference suppression filter (1) for a DC motor (2), which comprises two inductors (11, 12) having the same impedance (Z_{L}) and each arranged in a supply line (31, 32) and a Cx capacitor (13) arranged between the supply lines (31, 32) as well as a Cy capacitor (14) arranged between one of the two supply lines (31) and earth (M),
characterized in that
the impedance (Z_{L}) of the inductors (11, 12) is greater than a total impedance (Z_{Cx}+Z_{Cy1}) of the Cx capacitor (13) and the Cy capacitor (14), wherein an inductive component (L_{Cx}) of the impedance (Z_{Cx}) of the Cx capacitor (13) for a high-frequency interference current (S2) flowing in the other of the two supply lines (32) is smaller than or equal to an inductive component (L_{Cy1}) of an impedance (Z_{Cy1}) of the Cy capacitor (14); thus enabling the high-frequency interference current (S2) to flow away via the Cx capacitor (13) and the Cy capacitor (14) to earth (M).

6. The interference suppression filter (1) according to claim 1, characterized in that the inductive component (L_{Cx}) of the impedance (Z_{Cx}) of the Cx capacitor (13) and the inductive component (L_{Cx}) of the impedance (Z_{Cy1}) of the Cy capacitor (14) for a high-frequency interference current (S2) flowing in the other of the two supply lines (32) is smaller than the inductive component (L_{L}) of the impedance (Z_{L}) of the inductors (11, 12).

7. The interference suppression filter (1) according to claim 1, characterized in that an inductive component (L_{Cx}+L_{Cy1}) of the total impedance (Z_{Cx}+Z_{Cy1}) of the capacitors (13, 14) of the interference suppression filter (1) for a high-frequency interference current (S2) flowing in the other of the two supply lines (32) is smaller than an inductive component (L_{L}) of the impedance (Z_{L}) of the inductors (11, 12).

8. The interference suppression filter (1) according to claim 1, characterized in that the Cx capacitor and the Cy capacitor and the inductors are wired components.

9. The interference suppression filter (1) according to claim 1, characterized in that the first supply line (31) is connected to a positive pole (+) of a DC voltage source, wherein the second supply line (32) is connected to a negative pole (−) of the DC voltage source.

10. ADC motor (2) comprising an interference suppression filter (1) according to claim 1.

11. The DC motor (2) according to claim 10, characterized in that the interference suppression filter (1) is disposed in the region of the brush holder.

12. The interference suppression filter (1) according to claim 1, characterized in that the inductive component (L_{Cx}) of the impedance (Z_{Cx}) of the Cx capacitor (13) for a high-frequency interference current (S2) flowing in the other of the two supply lines (32) is smaller than the inductive component (L_{L}) of the impedance (Z_{L}) of the inductors (11, 12).

13. The interference suppression filter (1) according to claim 1, characterized in that the inductive component (L_{Cy1}) of the impedance (Z_{Cy1}) of the Cy capacitor (14) for a high-frequency interference current (S2) flowing in the other of the two supply lines (32) is smaller than the inductive component (L_{L}) of the impedance (Z_{L}) of the inductors (11, 12).

14. The interference suppression filter (1) according to claim 1, characterized in that the Cx capacitor and the Cy capacitor are wired components.

15. The interference suppression filter (1) according to claim 1, characterized in that the inductors are wired components.

16. The interference suppression filter (1) according to claim 1, characterized in that the first supply line (31) is either connected to a negative pole (−) of a DC voltage source, wherein the second supply line (32) is connected to a positive pole (+) of the DC voltage source.

17. (negative pole (−)) The DC motor (2) according to claim 10, wherein the DC motor (2) is for a motor vehicle.

18. The DC motor (2) according to claim 10, characterized in that the interference suppression filter (1) is disposed on the brush holder.
